(19) United States
(12) Patent Application Publication
(10) Pub. No.: US 2025/0160103 A1
(43) Pub. Date: May 15, 2025

(54) DISPLAY UNIT, DISPLAY DEVICE AND METHOD FOR PRODUCING A DISPLAY UNIT

(71) Applicant: ams-OSRAM International GmbH, Regensburg (DE)

(72) Inventor: Thomas Schwarz, Regensburg (DE)

(21) Appl. No.: 18/838,450

(22) PCT Filed: Feb. 2, 2023
(86) PCT No.: PCT/EP2023/052493

§ 371 Date: Aug. 14, 2024

(30) Foreign Application Priority Data
Feb. 21, 2022 (DE) 10 2022 103 970.6

(51) Int. Cl. H10H 29/85; H01L 25/075; H10H 29/01; H10H 29/80

(52) U.S. Cl. CPC H10H 29/857; H01L 25/0753; H10H 29/0364; H10H 29/942

(57) ABSTRACT

In an embodiment a display unit includes a first contact layer, a second contact layer, a plurality of connection region and a plurality of optoelectronic semiconductor components, wherein the first contact layer has a plurality of row lines at a row spacing from one another, wherein the second contact layer has a plurality of column lines at a column spacing from one another, wherein the first contact layer and the second contact layer are arranged stacked, wherein each of the connection regions electrically conductively connects at least one row line to at least one column line, and wherein the row spacing deviates by less than 50% from the column spacing.

### CROSS-REFERENCE TO RELATED APPLICATIONS

This patent application is a national phase filing under section 371 of PCT/EP2023/052493, filed Feb. 2, 2023, which claims the priority of German patent application 102022103970.6, filed Feb. 21, 2022, each of which is incorporated herein by reference in its entirety.

### TECHNICAL FIELD

A display unit, a display device and a method for producing a display unit are disclosed. The display unit and the display device are configured in particular for generating electromagnetic radiation, for example light perceptible to the human eye.

### SUMMARY

Embodiments provide a display unit that has a particularly high radiation permeability.

Further embodiments provide a display device that has a particularly high radiation permeability.

Yet other embodiments provide a method for producing a display unit that enables simplified manufacture.

For example, the display unit has an edge length of less than 20 mm, preferably less than 5 mm. The display unit is therefore particularly suitable for integration in a display device comprising a plurality of display units.

According to at least one embodiment, the display unit comprises a first contact layer and a second contact layer. The first contact layer and the second contact layer are at least partially formed with an electrically conductive material. In particular, the first contact layer and the second contact layer comprise a metal. The contact layers have a thickness of at least 0.1 μm and at most 50 μm. The thickness is defined here and in the following as an average extension of the contact layers transversely, in particular perpendicular to the main extension plane of the contact layers.

According to at least one embodiment, the display unit comprises a plurality of connection regions. The connection regions are formed in particular with an electrically conductive material.

According to at least one embodiment, the display unit comprises a plurality of optoelectronic semiconductor components. In particular, the optoelectronic semiconductor components are configured to generate electromagnetic radiation, for example light perceptible to the human eye. For example, the optoelectronic semiconductor component comprises a semiconductor body with a first region of a first conductivity, a second region of a second conductivity and an active region which is configured to emit electromagnetic radiation. Preferably, the first conductivity differs from the second conductivity. For example, the first region and the second region are formed with a doped semiconductor material. In particular, the active region has a pn junction, a double heterostructure, a single quantum well (SQW) structure or a multiple quantum well (MQW) structure for the generation of radiation or for radiation detection. The semiconductor components are, for example, luminescence diodes, in particular luminaire or laser diodes. For example, an optoelectronic semiconductor component is a μLED with an edge length in the range of μm or a miniLED with an edge length in the range of 100 μm.

Preferably, the display unit comprises an optoelectronic semiconductor component which is configured to emit electromagnetic radiation in the red spectral range, an optoelectronic semiconductor component which is configured to emit electromagnetic radiation in the green spectral range, and an optoelectronic semiconductor component which is configured to emit electromagnetic radiation in the blue spectral range. Advantageously, the display unit can thus form an RGB pixel.

According to at least one embodiment of the display unit, the first contact layer has a plurality of row lines at a row spacing from one another. The row lines are preferably formed with a metal. The row spacing corresponds here and in the following to an average distance between two directly adjacent row lines. The row spacing is in particular between 50 μm and 500 μm, preferably 150 μm. Preferably, at least some of the row lines are electrically separated from each other. For example, row lines are only electrically connected to each other in the region of a connection region. In particular, the row lines are not designed as a grid.

According to at least one embodiment of the display unit, the second contact layer has a plurality of column lines at a column spacing from one another. The column lines are preferably formed with a metal. For example, the column lines are formed with the same material as the row lines. The column spacing corresponds here and in the following to an average distance between two directly adjacent column lines. In particular, the column spacing is between 50 μm and 500 μm, preferably 150 μm. Preferably, the individual column lines are electrically separated from each other. For example, column lines are only electrically connected to each other in the region of a connection region. In particular, the column lines are not designed as a grid.

According to at least one embodiment of the display unit, the first contact layer and the second contact layer are arranged stacked. In other words, the first contact layer is arranged in a plane above or below the second contact layer. Such an arrangement of the contact layers results in an advantageously compact design of the display unit.

According to at least one embodiment of the display unit, the connection regions each connect at least one row line to at least one column line in an electrically conducting manner. In particular, a direct electrical connection between at least one row line and one column line is established in each of the connection regions. In other words, preferably no further components are connected between a row line and a column line in addition to a connection region. For example, a connection region overlaps with at least one column line and/or at least one further row line in a plan view of the display unit.

According to at least one embodiment of the display unit, the row spacing deviates from the column spacing by less than 50%. Preferably, the row spacing deviates from the column spacing by less than 20%. Particularly preferably, the row spacing deviates from the column spacing by less than 10%. The deviation here and in the following is a relative deviation of the row spacing (Z) from the column spacing(S) according to the following formula:

$$\vert \frac{Z - S}{Z} \vert \leq 0.5 ,$$

preferably

$$\vert \frac{Z - S}{Z} \vert \leq 0.2 ,$$

particularly preferred

$$\vert \frac{Z - S}{Z} \vert \leq 0.1 .$$

If the row spacing is equal to the column spacing, the display unit can have particularly few disturbing reflections for a human observer. In particular, the row spacing is equal to the column spacing.

The display unit is delimited laterally by outer edges. Preferably, the outer edges form a rectangle, in particular a square. In particular, the row lines and the column lines are each aligned parallel to an outer edge of the display unit.

According to at least one embodiment, the display unit comprises:
a first contact layer,
a second contact layer,
a plurality of connection regions, and
a plurality of optoelectronic semiconductor components, wherein
the first contact layer has a plurality of row lines at a row spacing from each other,
the second contact layer has a plurality of column lines at a column spacing from each other,
the first contact layer and the second contact layer are arranged stacked,
the connection regions each electrically conductively connect at least one row line to at least one column line, and
the row spacing deviates from the column spacing by less than 50%.

A display unit described herein is based on the following considerations, among others: The production of at least partially radiation permeable display units opens up new areas of application. The radiation permeability of known display units can exhibit an undesirable dependence on a viewing angle. For example, the radiation permeability of contact layers of a display unit can deteriorate significantly at viewing angles other than 0° and thus create an undesirable impression on the viewer.

The display unit described herein makes use, among other things, of the idea of arranging a plurality of row lines in a first contact layer and a plurality of column lines in a second contact layer. By a stacked arrangement of the first contact layer and the second contact layer and the use of a plurality of row lines and column lines with a uniform row and column spacing, a particularly high radiation permeability can be achieved, which has an advantageously low dependence on a viewing angle.

According to at least one embodiment of the display unit, the connection regions each comprise a plurality of connection elements. In particular, each connection element connects a row line to a column line in an electrically conducting manner. An increased number of connection elements makes it particularly easy to scale the current-carrying capacity of a connection region.

According to at least one embodiment of the display unit, the connection elements are each arranged at crossing points of a row line and a column line. A crossing point occurs, for example, where a distance between a column line and a row line is at a minimum. In a top view of the display unit at a viewing angle of 0°, the crossing points appear in particular as the intersection of a row line and a column line. Advantageously, connection elements at intersections of a row line and a column line are particularly inconspicuous to an observer.

According to at least one embodiment of the display unit, the connection elements are formed with a metal. For example, the connection elements are formed with a galvanically deposited metal. For example, the connection elements are formed with metal threads. Advantageously, metal threads have a particularly low expansion. In this way, an advantageously high radiation permeability can be achieved. Alternatively, the connection elements are formed with an electrically conductive metal paste, in particular a silver paste. Advantageously, a metal paste is particularly easy to process.

According to at least one embodiment of the display unit, the connection regions are formed with a radiation permeable and electrically conductive material. Here and in the following, radiation permeable means permeable to electromagnetic radiation in the visible spectral range. The visible spectral range is defined here and in the following as electromagnetic radiation with a wavelength in the range between 380 nm and 780 nm. For example, the connection regions are formed with one of the following materials: Poly-3,4-ethylenedioxythiophene doped with polystyrene sulfonate (PEDOT:PSS), poly-3,4-ethylenedioxythiophene doped with tosylate (PEDOT:Tos), carbon nanotubes, graphene flakes, metal nanowires, in particular silver nanowires. These materials are advantageously radiation permeable and have high electric conductivity.

According to at least one embodiment of the display unit, the first contact layer and the second contact layer are arranged on a radiation permeable substrate. Preferably, the substrate is formed with an electrically insulating material. The substrate is formed in particular with one of the following materials: Polyethylene terephthalate (PET), Polyethylene naphthalate (PEN), Polyimide (PI). The substrate has a thickness of between 20 μm and 200 μm, preferably between 50 μm and 100 μm.

According to at least one embodiment of the display unit, the first contact layer is arranged on a side of the substrate opposite the second contact layer. Advantageously, this results in a particularly simple structure of the display unit, since the substrate itself is arranged as an electrical insulator between the first contact layer and the second contact layer.

According to at least one embodiment of the display unit, the first contact layer and the second contact layer are arranged on a common side of the substrate. The arrangement of the first contact layer and the second contact layer is thus carried out from the common side. This simplifies the manufacture of the display unit, for example.

According to at least one embodiment of the display unit, the first contact layer is arranged on a substrate and the second contact layer is arranged on a cover layer. In particular, the cover layer is permeable to electromagnetic radiation in the visible spectral range. Preferably, the cover layer is electrically insulating. For example, the second contact layer is already arranged on the cover layer in a separate manufacturing step. The cover layer preferably has a thickness of between 20 μm and 200 μm, preferably between 50 μm and 100 μm.

According to at least one embodiment of the display unit, a radiation permeable joining layer is arranged between the substrate and the cover layer. For example, the joining layer is formed with one of the following materials: Polyvinyl butyral (PVB), ethylene-vinyl acetate copolymer (EVA), photoresist, polymer film. In particular, the joining layer is formed with a perforated laminating film.

According to at least one embodiment of the display unit, the row lines and the column lines intersect at an intersection angle of at least 45°. Preferably, the row lines and the column lines intersect at an intersection angle of between 89° and 90°, preferably at 90°. An intersection angle that is as large as possible is advantageous so that the first contact layer and the second contact layer are as imperceptible as possible to an observer.

According to at least one embodiment of the display unit, the row lines and the column lines have a constant width. In other words, the row lines and the column lines each have the same width over their length. Here and in the following, the width is to be understood as a lateral expansion of the row line or the column line transverse to the main direction of extension of the respective row line or column line. Preferably, the width of the row lines corresponds to the width of the column lines. For example, the row lines have a width of at least 2 μm and at most 20 μm. For example, the column lines have a width of at least 2 μm and at most 20 μm. Preferably, the row lines and the column lines have a width of 10 μm.

According to at least one embodiment of the display unit, the row lines and column lines have separations. Here and in the following, separations are to be understood as an interruption in a row line or column line. Advantageously, the separations have a lateral extension of at least 10 μm. In this way, sufficient electrical insulation can be achieved between the ends of the row line or column line adjacent to the separation.

In particular, the lateral expansion of the separations corresponds to at most half the row spacing or the column spacing. The shortest possible separation is particularly imperceptible to a human observer.

A method for producing a display unit is further disclosed. In particular, the display unit can be produced by means of the method described herein. This means that all features disclosed in connection with the display unit are also disclosed for the method for producing a display unit and vice versa.

According to at least one embodiment, the method comprises providing a first contact layer on a substrate. In particular, the first contact layer is deposited on the first substrate. The first substrate is preferably designed to be radiation permeable. For example, the first substrate has sufficient mechanical stability to be mechanically self-supporting.

According to at least one embodiment, the method comprises providing a second contact layer. The second contact layer is arranged, for example, on the first contact layer.

According to at least one embodiment, the method comprises structuring the first contact layer into a plurality of row lines at a row spacing from one another. In particular, the first contact layer is initially produced by depositing a material over the entire surface, which is then at least partially removed again.

According to at least one embodiment, the method comprises structuring the second contact layer into a plurality of column lines at a column spacing from one another. In particular, the second contact layer is first produced by depositing a material over the entire surface, which is then at least partially removed again.

According to at least one embodiment, the method comprises forming a plurality of connection regions, each of which electrically conductively connects at least one row line to at least one column line.

According to at least one embodiment, the method comprises arranging a plurality of optoelectronic semiconductor components on the display unit. Preferably, the optoelectronic semiconductor components are arranged on the first contact layer. In particular, an optoelectronic semiconductor component is arranged in each case at positions of a row line at which a separation is present. Preferably, an optoelectronic semiconductor component spans a separation in a row line.

According to at least one embodiment, the method comprises the steps of:
providing a first contact layer on a substrate,
providing a second contact layer,
structuring the first contact layer into a plurality of row lines at a row spacing from each other,
structuring the second contact layer into a plurality of column lines at a column spacing from each other,
forming a plurality of connection regions, each of which electrically conductively connects at least one row line to at least one column line,
arranging a plurality of optoelectronic semiconductor components on the display unit.

According to at least one embodiment of the method, the second contact layer is arranged on a side of the substrate opposite the first contact layer. In particular, the substrate thus acts as an electrical insulator between the first contact layer and the second contact layer.

According to at least one embodiment of the method, the connection region is introduced into a recess in the substrate. The connection region is formed in particular with a radiation permeable material. The recess preferably extends completely through the substrate. For example, the recess is completely filled with the material of the connection region.

According to at least one embodiment of the method, the first contact layer is arranged on a side of the second contact layer facing away from the substrate. In other words, the first contact layer is arranged on the second contact layer. In particular, the first contact layer is arranged directly on the second contact layer.

According to at least one embodiment of the method, the second contact layer is arranged and structured on a second radiation permeable cover layer. The cover layer is formed in particular with the material of the substrate.

According to at least one embodiment of the method, the substrate and the cover layer are joined together via a joining layer. For example, a plurality of recesses is arranged in the joining layer. In particular, the joining layer is formed as a perforated laminating film. The connection regions are formed in the recesses of the joining layer, for example.

According to at least one embodiment of the method, a plurality of optoelectronic semiconductor components is mounted on the substrate before the second contact layer is arranged. In other words, the optoelectronic components are arranged between the first contact layer and the second contact layer. Advantageously, the optoelectronic semiconductor components are thus particularly well protected from external influences.

According to at least one embodiment of the method, connection regions are mounted on the substrate before the second contact layer is arranged. In particular, the connection regions are formed with balls of a conductive paste which displace the material of the joining layer.

According to at least one embodiment of the method, the first and second contact layers are structured by means of nano-imprint and, if necessary, dry-chemically. Nano-imprint is to be understood here and in the following as a method in which a molded layer is mechanically structured with a stamp. In particular, the structures have sizes of a few μm or nm.

According to at least one embodiment of the method, first and second contact layers are deposited galvanically. For example, a starting layer is first deposited by sputtering. Further material can then be deposited on the starting layer by means of galvanization.

A display device is further disclosed. In particular, the display device comprises a plurality of display units described herein. This means that all features disclosed in connection with the display unit are also disclosed for the display device and vice versa.

According to at least one embodiment, the display device comprises a plurality of display units. Preferably, each display unit forms an RGB pixel. In particular, all display units can be controlled individually.

In particular, the display device comprises a frame body. For example, the display units are arranged in the frame body. The frame body preferably surrounds the display units completely. The frame body has a rectangular shape with opposite outer sides aligned parallel to each other.

The row lines or the column lines of the display units are aligned in particular parallel to an outer side of the frame body of the display device.

A display unit described herein is particularly suitable for use in transparent displays. In particular for an automobile rear, front or side window symbol, an automobile rear light with a transparent look or an advertising display in glass windows of shopping centers.

### BRIEF DESCRIPTION OF THE DRAWINGS

Further advantages and advantageous configurations and further embodiments of the display unit result from the following exemplary embodiments shown in connection with the figures.

FIG. 1 shows a schematic top view of a display unit described herein according to a first exemplary embodiment;

FIG. 2 shows a schematic top view of a display unit described herein according to a second exemplary embodiment;

FIG. 3 shows a schematic sectional view of a display unit described herein according to a third exemplary embodiment;

FIGS. 4A to 4D show schematic sectional views of a display unit described herein according to the third exemplary embodiment at various stages of a method for its production;

FIG. 5 shows a schematic top view of a display unit described herein according to a fourth embodiment;

FIG. 6 shows a schematic sectional view of a display unit described herein according to a fifth embodiment;

FIGS. 7A to 7L show schematic sectional views of a display unit according to the fifth exemplary embodiment described herein at various stages of a method for its production;

FIG. 8 shows a schematic sectional view of a display unit described herein according to a sixth exemplary embodiment;

FIGS. 9A to 9F show schematic sectional views of a display unit described herein according to the sixth exemplary embodiment at various stages of a method for its production;

FIG. 10 shows a schematic sectional view of a display unit described herein according to a seventh embodiment;

FIGS. 11A to 11C show schematic sectional views of a display unit described herein according to an eighth embodiment in various stages of a method for its production;

FIG. 12 shows a schematic sectional view of a display unit described herein according to a ninth embodiment; and

FIG. 13 shows a schematic top view of a display device described herein according to a first exemplary embodiment.

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

### DETAILED DESCRIPTION OF ILLUSTRATIVE EMBODIMENTS

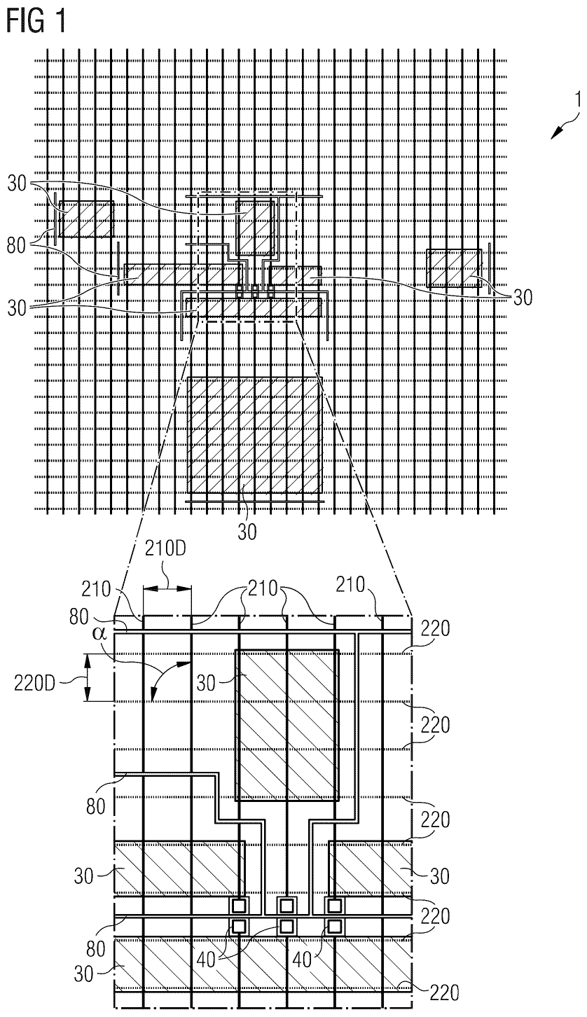

FIG. 1 shows a schematic top view of a display unit 1 described herein according to a first exemplary embodiment. The display unit 1 comprises a first contact layer 21 with a plurality of row lines 210 and a second contact layer 22 with a plurality of column lines 220. The row lines 210 each have a constant width of 10 μm over their length. The row lines 210 are arranged at a row spacing 210D of 150 μm from one another. At least some of the row lines 210 are electrically disconnected from each other.

The column lines 210 each have a constant width of 10 μm over their length. The column lines 220 are arranged at a column spacing 220D of 150 μm from one another. At least some of the column lines 220 are electrically disconnected from each other.

The row lines 210 are arranged parallel to each other. The column lines 220 are arranged parallel to each other. The row lines 210 intersect the column lines 220 at an intersection angle α of 90°. The width of the row lines 210 corresponds to the width of the column lines 220. The row spacing 210D corresponds to the column spacing 220D. In this way, a particularly high radiation permeability of the display unit 1 can be advantageously achieved.

Furthermore, the display unit 1 comprises a plurality of connection regions 30 and separations 80. The connection regions 30 are formed with a radiation permeable material, in particular PEDOT:PSS. The connection regions 30 each connect at least one row line 201 to at least one column line 220 in an electrically conducting manner. In particular, a direct electrical connection between at least one row line 210 and one column line 220 is established in each of the connection regions 30. In other words, preferably no further components are connected between a row line 210 and a column line 220 in addition to a connection region 30.

For example, row lines 210 are only electrically connected to one another in the region of a connection region 30. In particular, column lines 220 are only electrically connected to one another in the region of a connection region 30.

The separations 80 are each designed as an interruption in a row line 210 or a column line 220. The separations 80 have a lateral extension of at least 10 μm. In particular, the lateral expansion of the separations 80 corresponds to at most half of the row spacing 210D or the column spacing 220D. A separation 80 that is as short as possible is advantageously particularly imperceptible to a human observer.

By means of the separations 80 and the connection regions 30, several row lines 210 and column lines 220 are connected to each other in such a way that they are at a common electrical potential.

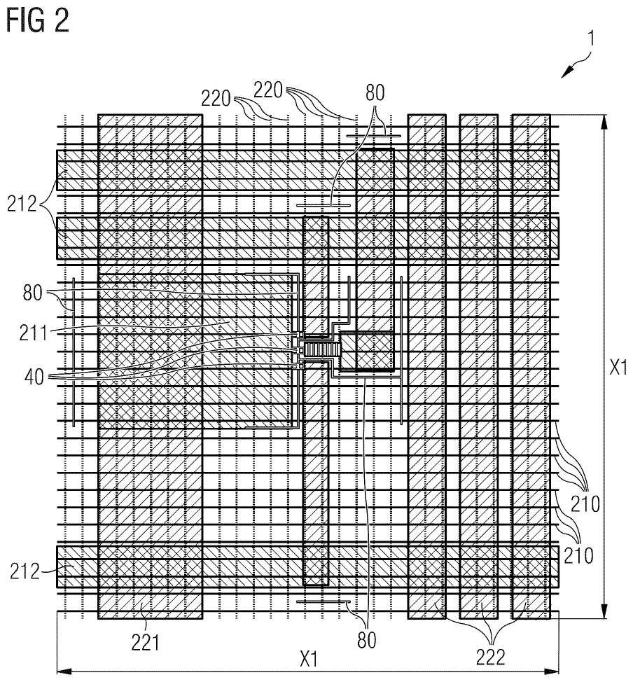

FIG. 2 shows a schematic top view of a display unit 1 described herein according to a second exemplary embodiment. The second exemplary embodiment shown in FIG. 2 essentially corresponds to the first exemplary embodiment shown in FIG. 1. In the second exemplary embodiment, first row line bundles 211, second row line bundles 212, first column line bundles 221 and second column line bundles 222 are shown for symbolic illustration. Each row line bundle 211, 212 comprises a plurality of row lines 210. Each column line bundle 221, 222 comprises a plurality of column lines 220.

The row lines 210 of a row line bundle 211, 212 and the column lines 220 within a column line bundle 221, 222 are each at a common electrical potential. All lines within a bundle 211, 212, 221, 222 act as a common electrical conductor.

By means of the first row line bundle 211 and the first column line bundle 221, an electrical connection is made to the common anode of the optoelectronic semiconductor components 40. The first row line bundle 211 comprises 9 directly adjacent row lines 210. By means of the second row line bundle 212 and the second column line bundle 222, a separate connection is made in each case to a cathode of an optoelectronic semiconductor component 40.

The display unit 1 has a rectangular shape with an edge length X1 of 3 mm.

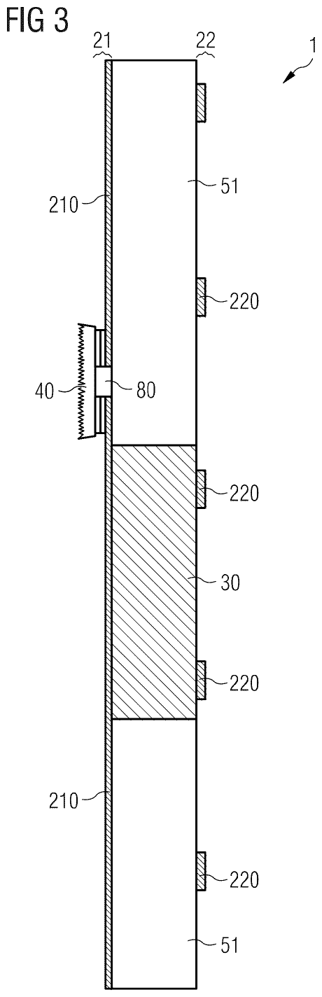

FIG. 3 shows a schematic sectional view of a display unit described herein according to a third exemplary embodiment. The second exemplary embodiment shown in FIG. 3 essentially corresponds to the first exemplary embodiment shown in FIG. 1. The row lines 210 of the first contact layer 21 are arranged on a first side of a radiation permeable substrate 51. The column lines 220 of the second contact layer 22 are arranged on a side of the substrate 51 opposite the first contact layer 21. The substrate 51 is electrically insulating. The substrate has a thickness of between 20 μm and 200 μm, preferably between 50 μm and 100 μm.

The row lines 210 and the column lines 220 preferably comprise a dark coating on their sides facing away from the optoelectronic semiconductor component 40. The dark coating is formed with palladium, for example. By means of the dark coating, interfering reflections of the column lines 210 and the row lines 220 can be reduced for an observer. The palladium is applied to the row lines 210 and the column lines 220 in particular by galvanization or by means of physical vapor deposition (PVD).

In the connection region 30, a radiation permeable and electrically conductive material extends completely through the substrate 51. The connection region 30 connects at least one row line 210 to two column lines 220 in an electrically conducting manner. The optoelectronic semiconductor component 40 is oriented such that a main radiation direction of the semiconductor component 40 points in a direction facing away from the substrate 51.

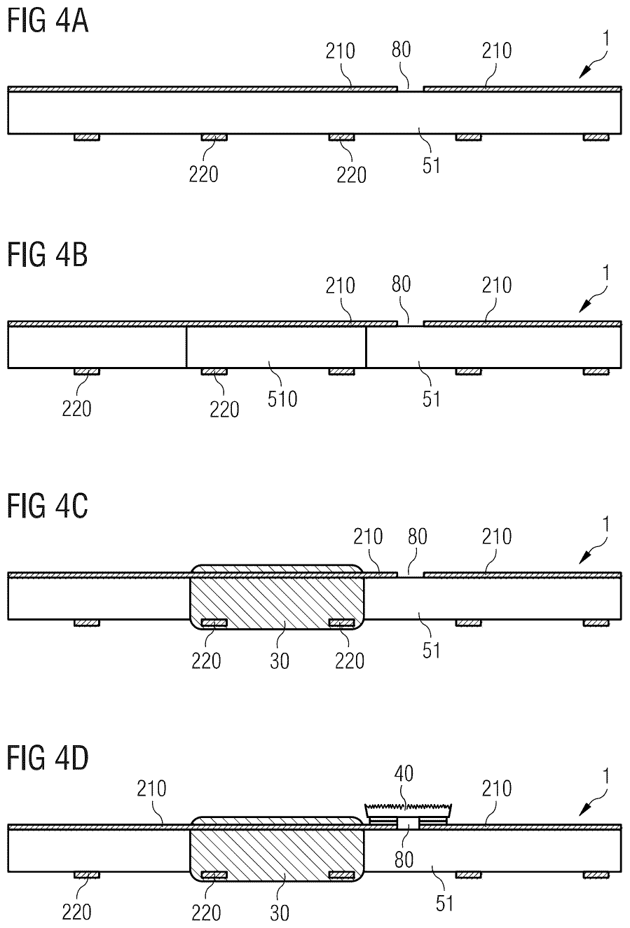

FIGS. 4A to 4D show schematic sectional views of a display unit 1 described herein according to the third exemplary embodiment at various stages of a method for its production.

FIG. 4A shows a first step of the method in which a substrate 51 is provided. The substrate 51 is formed with a radiation permeable material, in particular PET. The substrate 51 is mechanically self-supporting. A first contact layer 21 with a plurality of row lines 210 is arranged on a first side of the substrate 51. A second contact layer 22 with a plurality of column lines 220 is arranged on a side of the substrate 51 opposite the first contact layer 21. For example, the first contact layer 21 and the second contact layer 22 are deposited on the substrate 51 using a galvanic deposition method.

At least one row line 210 is interrupted in places by a separation 80. The separation 80 is produced, for example, by a photolithographic method, by laser ablation or by a nano-imprint method.

FIG. 4B shows a further step of the method in which a recess 510 is formed in the substrate 51. The recess 510 extends completely through the substrate 51. The recess 510 is formed in the substrate 51 for example by laser ablation, by dry chemical etching or by wet chemical etching.

FIG. 4C shows a further step of the method in which a material of a connection region 30 is introduced into the recess 510. The connection region 30 is formed with PEDOT:PSS and is radiation permeable.

FIG. 4D shows a further step of the method in which an optoelectronic semiconductor component 40 is arranged on the row line 210. The optoelectronic semiconductor component 40 spans the separation 80 in the row line 210. In particular, the optoelectronic semiconductor component 40 is mounted by soldering.

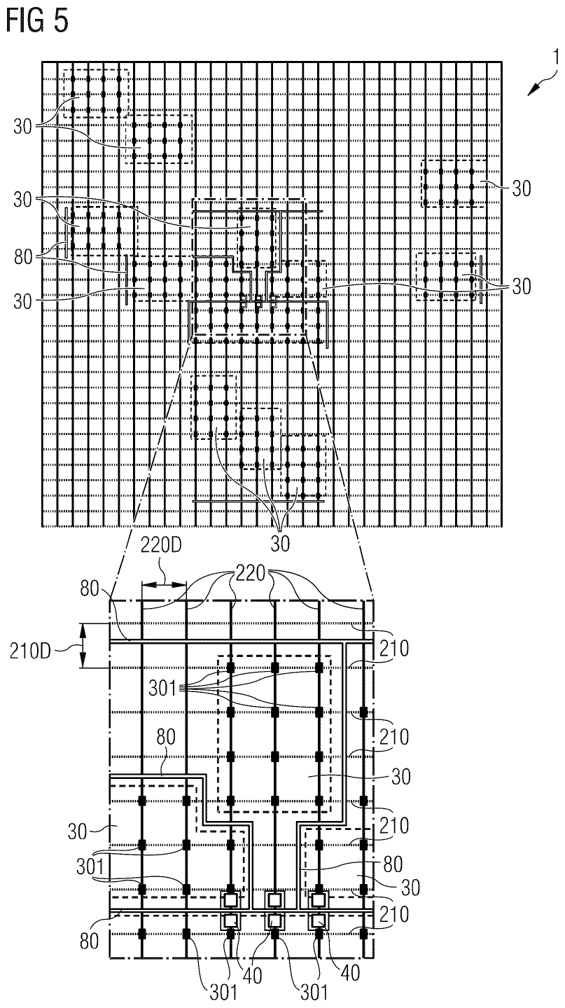

FIG. 5 shows a schematic top view of a display unit 1 described herein according to a fourth exemplary embodiment. The fourth exemplary embodiment shown in FIG. 5 essentially corresponds to the first exemplary embodiment shown in FIG. 1. In contrast to the first exemplary embodiment, the connection regions 30 each comprise a plurality of connection elements 301. Each connection element 301 connects a row line 210 to a column line 220 in an electrically conducting manner. Due to an increased number of connection elements 301, a current-carrying capacity of a connection region 30 is particularly easy to scale.

In particular, a direct electrical connection between a row line 210 and a column line 220 is established by a respective connection element 301. In other words, preferably no other components are connected between a row line 210 and a column line 220 in addition to a connection element 301.

Row lines 210 are only electrically connected to each other in the region of the connection region 30. Column lines 220 are only electrically connected to each other in the region of the connection region 30.

The connection elements 301 are each arranged at crossing points of a row line 210 and a column line 220. A crossing point occurs where a distance between a column line 210 and a row line 220 is at a minimum. In a top view of the display unit at a viewing angle of 0°, the crossing points appear in particular as the intersection of a row line 210 and a column line 220. The connection elements 301 are particularly inconspicuous to an observer at crossing points of a row line 210 and a column line 220.

The connection elements 301 are formed with a metal. For example, the connection elements 301 are formed with an electrodeposited metal.

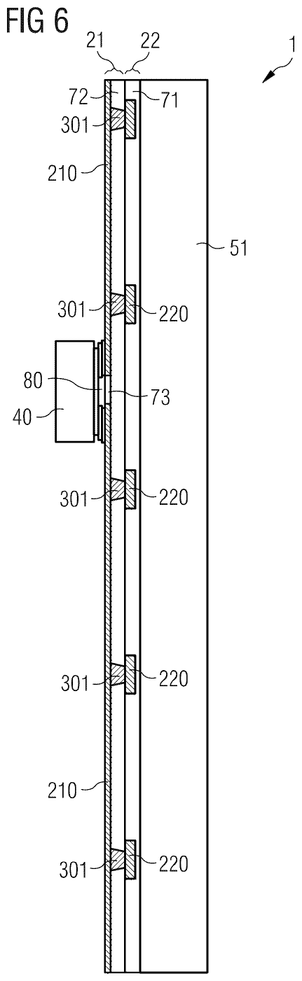

FIG. 6 shows a schematic sectional view of a display unit 1 described herein according to a fifth exemplary embodiment. The display unit 1 comprises an optoelectronic semiconductor component 40, a radiation permeable substrate 51, a first contact layer 21 and a second contact layer 22. The second contact layer 22 is arranged on the substrate 51 and comprises a plurality of column lines 220, which are embedded in a first isolation layer 71. The first isolation layer 71 is formed, for example, with polymer, in particular acrylic. The first contact layer 21 is arranged on the second contact layer 22 and comprises a plurality of row lines 210.

Further, the display unit comprises a plurality of connection elements 301 embedded in a second isolation layer 72. The second isolation layer 72 is formed, for example, with polymer, in particular acrylic. Preferably, the second isolation layer 72 is formed with the same material as the first isolation layer 71.

The connection elements 301 extend from the second contact layer 22 into the first contact layer 21. The contact layers 21, 22 have a thickness of at least 0.1 μm and at most 50 μm. Each connection element 301 electrically conductively connects a row line 210 to a column line 220. The connection elements 301 are each arranged at crossing points of a row line 210 and a column line 220.

The connection elements 301 are formed with a metal. For example, the connection elements 301 are formed with an electrodeposited metal.

The optoelectronic semiconductor component 40 is arranged on the row line 210. The optoelectronic semiconductor component 40 spans the separation 80 in the row line 210. In particular, the optoelectronic semiconductor component 40 is mounted by soldering. A third isolation layer 73 is arranged in the separation 80, which enables improved electrical isolation. The third isolation layer 73 is formed, for example, with polymer, in particular with acrylic. In particular, the third isolation layer 73 is formed with the same material as the second isolation layer 72.

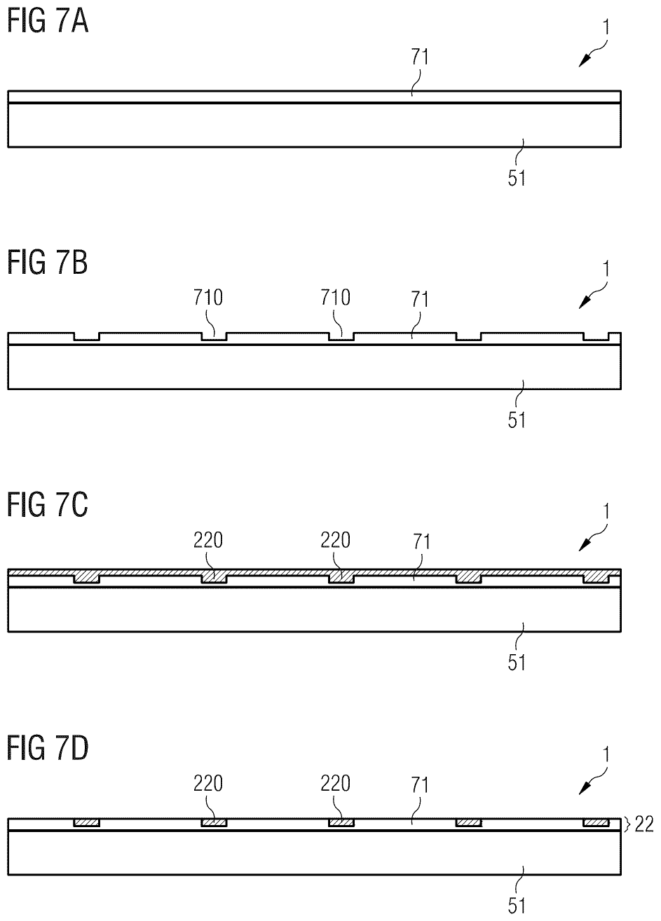

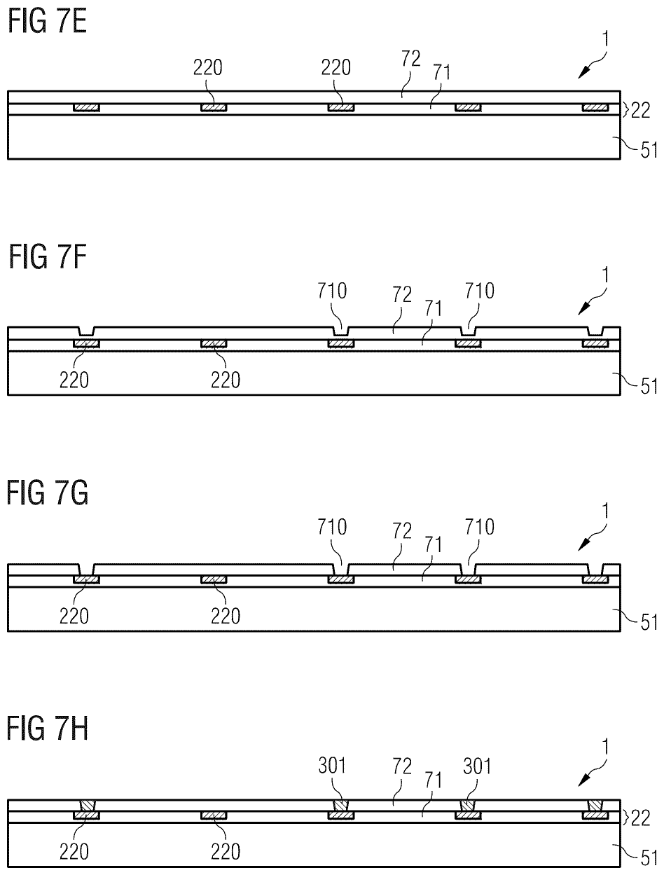

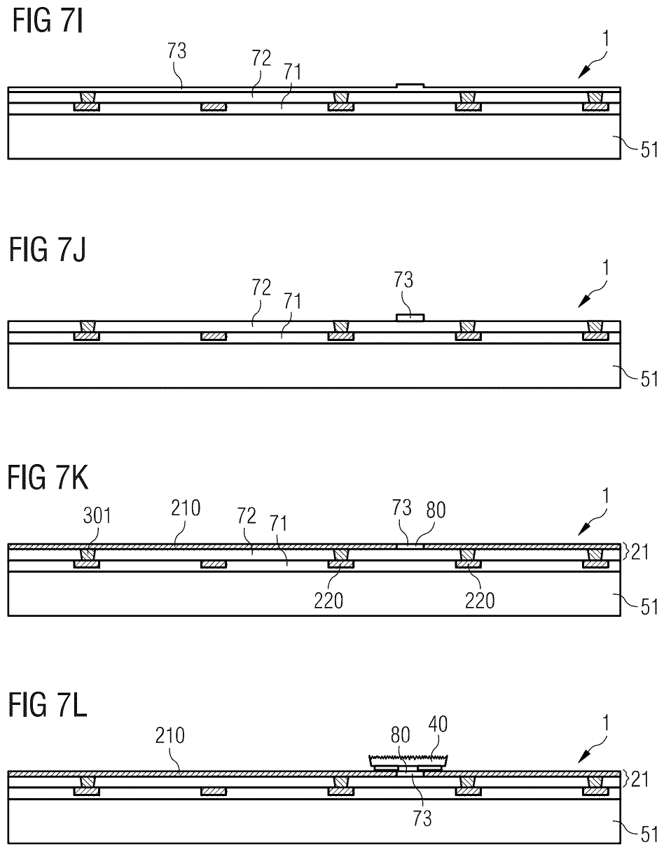

FIGS. 7A to 7L show schematic sectional views of a display unit 1 described herein according to the fifth exemplary embodiment at various stages of a method for its production.

FIG. 7A shows a first step of the method in which a substrate 51 is provided. The substrate 51 is formed with a radiation permeable material, in particular PET. The substrate 51 is mechanically self-supporting. A first isolation layer 71 is applied to a first side of the substrate 51. The first isolation layer 71 is formed with a polymer, in particular acrylic. The first isolation layer 71 is configured to be radiation permeable.

FIG. 7B shows a further step of the method in which the first isolation layer 71 is structured using a nano-imprint method. A plurality of depressions 710 are formed in a side of the first isolation layer 71 facing away from the substrate 51. For example, a stamp made of a polysiloxane is used to mechanically introduce the depressions 710 into the first isolation layer 71.

FIG. 7C shows a further step of the method in which a material of column lines 220 is deposited over the entire surface on the side of the first isolation layer 71 facing away from the substrate 51. For example, a starting layer is first deposited by sputtering and then material is deposited by galvanic deposition. Preferably, metal is deposited.

FIG. 7D shows a further step of the method, in which the side of the first isolation layer 71 facing away from the substrate 51 is polished and ground to remove some of the material of the column lines 220. Only the portion of the material located in the depressions 710 remains. This forms a second contact layer 22 with separated column lines 220. Consequently, the second contact layer 22 is embedded in the radiation permeable first isolation layer 71.

FIG. 7E shows a further step of the method, in which a second isolation layer 72 is applied to the second contact layer 22. The second isolation layer 72 is formed with a polymer, in particular acrylic. The second isolation layer 72 is made radiation permeable. In particular, the material of the second isolation layer 72 is identical to the first isolation layer 71 in the second contact layer 22.

FIG. 7F shows a further step of the method in which the second isolation layer 72 is structured using a nano-imprint method. A plurality of depressions 710 are formed in a side of the second isolation layer 72 facing away from the substrate 51. The depressions 710 are each laterally aligned with a column line 220.

A thin layer of the second isolation layer 72 remains on the side of the column lines 220 facing away from the substrate 51.

FIG. 7G shows a further step of the method, in which the column lines 220 are each exposed by means of an etching process. Consequently, the remaining thin layer of the second isolation layer 72 is removed from the side of the column lines 220 facing away from the substrate 51. For example, the entire surface is removed using a dry chemical etching process.

FIG. 7H shows a further step of the method, in which a plurality of connection elements 301 are arranged in the depressions 710. The material of the connection elements 301 is deposited over the entire surface on the side of the second contact layer 22 facing away from the substrate 51. For example, a starting layer is first deposited by sputtering and then material is deposited by galvanic deposition. Preferably, metal is deposited.

Subsequently, the side of the second contact layer 22 facing away from the substrate 51 is polished and ground to remove a portion of the material of the connection elements 301. Only the portion of the material located in the depressions 710 remains. As a result, a plurality of separate connection elements 301 are formed. In particular, the connection elements 301 extend from the second contact layer 22 into the first contact layer 21. The connection elements 301 are embedded in the second isolation layer 72.

FIG. 7I shows a further step of the method, in which a third isolation layer 73 is applied to the second isolation layer 72. The third isolation layer 73 is formed with a polymer, in particular acrylic. The third isolation layer 73 is configured to be radiation permeable. In particular, the material of the third isolation layer 73 is identical to the second isolation layer 72.

The third isolation layer 73 is then structured using a nano-imprint method. The structuring is carried out in such a way that at least one elevation is formed in the third isolation layer 73.

FIG. 7J shows another step of the method, in which the third isolation layer 73 is etched over the entire surface. The third isolation layer 73 is partially removed, so that surfaces of the connection elements 301 facing away from the substrate 51 are free of the third isolation layer 73 and an elevation formed in the previous step remains in the third isolation layer 73.

FIG. 7K shows another step of the method, in which a first contact layer 21 having a plurality of row lines 210 is applied to the second isolation layer 72.

As with the second contact layer, the second contact layer is first deposited over the entire surface and then at least partially removed again by grinding and polishing. This results in a separation of the row line 210 at the points where the third isolation layer 73 is still present.

FIG. 7L shows a further step of the method, in which an optoelectronic semiconductor component 40 is arranged on the row line 210.

Alternatively, the steps shown in FIGS. 7I, 7J and 7K can already be carried out together with the step shown in FIG. 7F. In particular, a thickness of the second isolation layer 72 is increased for this purpose, so that the nano-imprint method can be used to simultaneously form an elevation in the second isolation layer 72 in addition to the depressions 710 for the connection elements 301. In the same step, further depressions 710 for a first contact layer 210 with a plurality of row lines 210 can also be formed on the second isolation layer 72. Advantageously, the method for production can thus be shortened.

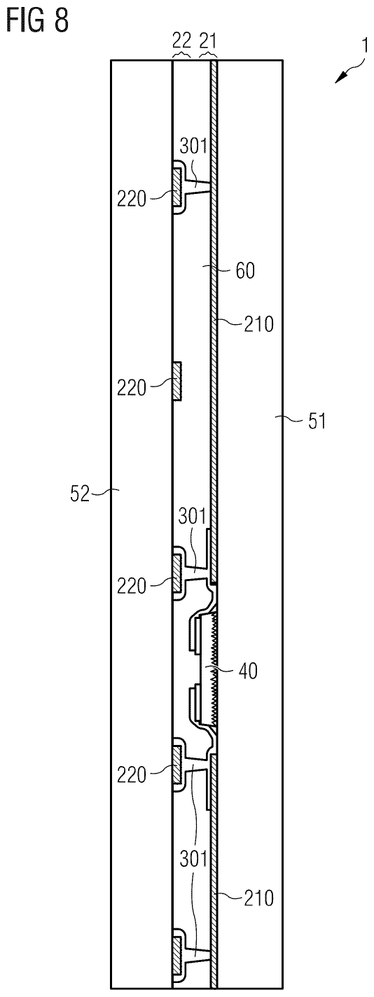

FIG. 8 shows a schematic sectional view of a display unit 1 described herein according to a sixth exemplary embodiment. The display unit 1 comprises a substrate 51 on which a first contact layer 21 with a plurality of row lines 210 and an optoelectronic semiconductor component 40 are arranged. The optoelectronic semiconductor component 40 is oriented such that a main radiation direction of the semiconductor component 40 points in a direction facing the substrate 51. The radiation is therefore emitted through the substrate 51.

Furthermore, the display unit 1 comprises a cover layer 52 on which a second contact layer 22 with a plurality of column lines 220 is arranged. The substrate 51 is designed to be radiation permeable. The cover layer 52 is designed to be radiation permeable. The cover layer 52 has a thickness of between 20 μm and 200 μm, preferably between 50 μm and 100 μm.

A joining layer 60 is arranged between the substrate 51 and the cover layer 52, which is formed with a radiation permeable material. In particular, the joining layer 60 is formed with a photosensitive material or a perforated PVB or an EVA. The joining layer 60 comprises a plurality of recesses, each of which is filled with a connection element 301. The connection elements 301 are formed, for example, with a metal paste, in particular a silver paste.

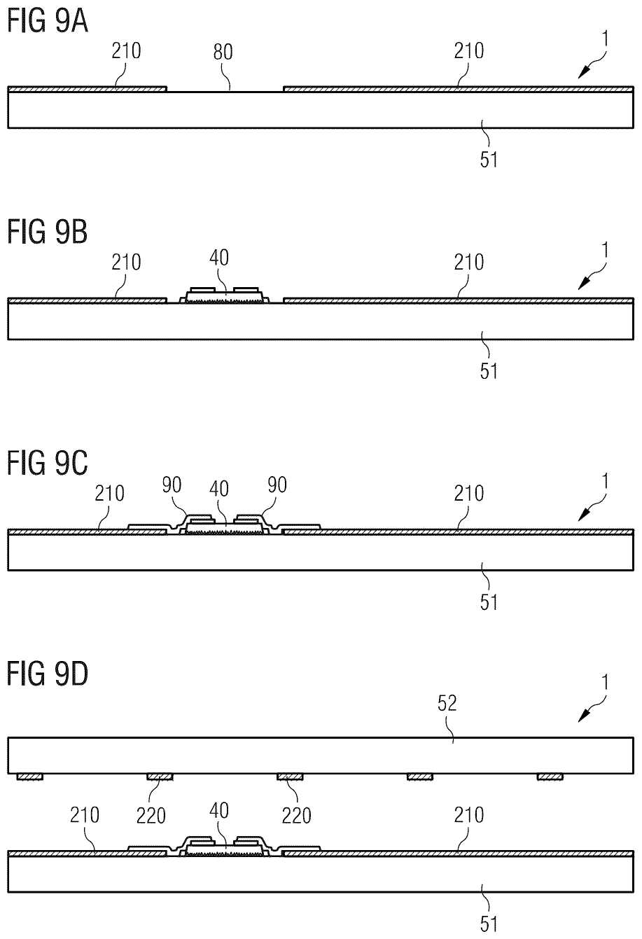

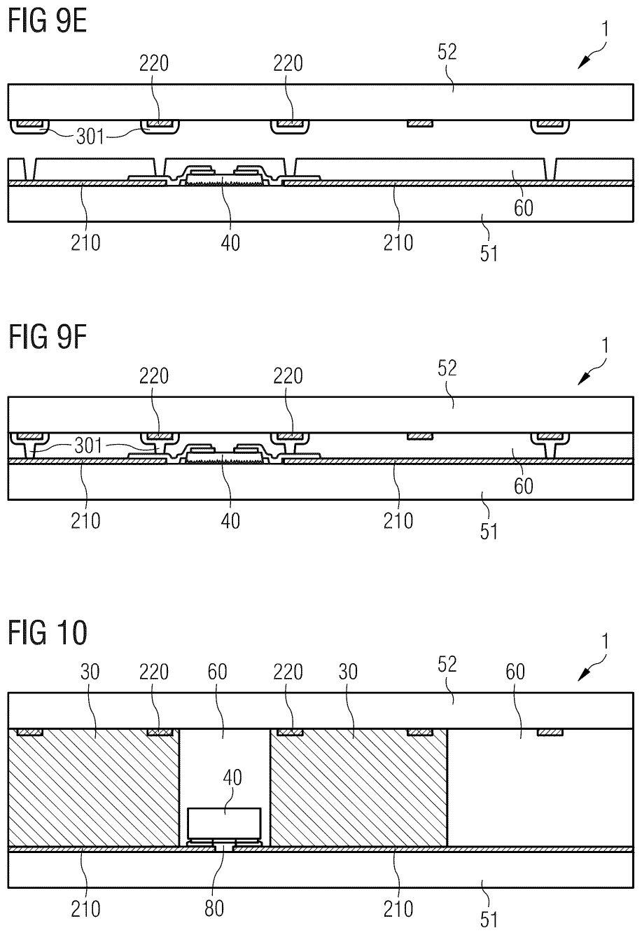

FIGS. 9A to 9F show schematic sectional views of a display unit 1 described herein according to the sixth exemplary embodiment at various stages of a method for its production.

FIG. 9A shows a first step of the method in which a radiation permeable substrate 51 is provided. A first contact layer 21 with a plurality of row lines 210 is arranged on the substrate 51. At least one row line 210 has an interruption in the form of a separation 80.

FIG. 9B shows another step of the method in which an optoelectronic semiconductor component 40 is arranged on the substrate 51. In contrast to the preceding embodiments, in the sixth embodiment, the optoelectronic semiconductor component 40 is arranged on the substrate 51 such that a main emission direction passes through the substrate 51. Further, the optoelectronic semiconductor component 40 is arranged so as to be completely disposed within the separation 80.

FIG. 9C shows a further step of the method, in which the optoelectronic semiconductor component 40 is electrically connected to the ends of the row line 210 via terminal elements 90. The terminal elements 90 are formed, for example, with a metal paste, in particular a silver paste. Preferably, the terminal elements 90 are applied using a printing process.

FIG. 9D shows a further step of the method in which a cover layer 52 with a second contact layer 22 is provided. The second contact layer 22 is produced by a method analogous to the first contact layer 21 and comprises a plurality of column lines 220.

FIG. 9E shows a further step of the method in which a joining layer 60 is arranged on the substrate 51. A plurality of recesses is arranged in the joining layer 60. The joining layer 60 is formed with one of the following materials: Polyvinyl butyral (PVB), ethylene-vinyl acetate copolymer (EVA), photoresist, polymer film. In particular, the joining layer 60 is formed with a perforated laminating film. Furthermore, a material of a connection element 301 is applied to at least some column lines 220. The cover layer 52 is aligned laterally to the substrate 51. The cover layer 52 is aligned in such a way that the column lines 220 are laterally aligned with the recesses in the joining layer 60.

FIG. 9F shows a further step of the method in which the cover layer 52 is applied to the joining layer 60. The material of the connection elements 301 is at least partially pressed into the recesses of the joining layer 60 and extends up to the first contact layer 21. The connection elements 301 are consequently formed in the recesses of the joining layer 60.

FIG. 10 shows a schematic sectional view of a display unit 1 described herein according to a seventh exemplary embodiment. The seventh exemplary embodiment shown in FIG. 10 essentially corresponds to the sixth exemplary embodiment shown in FIG. 8. In contrast to the sixth exemplary embodiment, the connection region 30 comprises a radiation permeable material and the optoelectronic semiconductor component 40 is configured to emit through the cover layer 52.

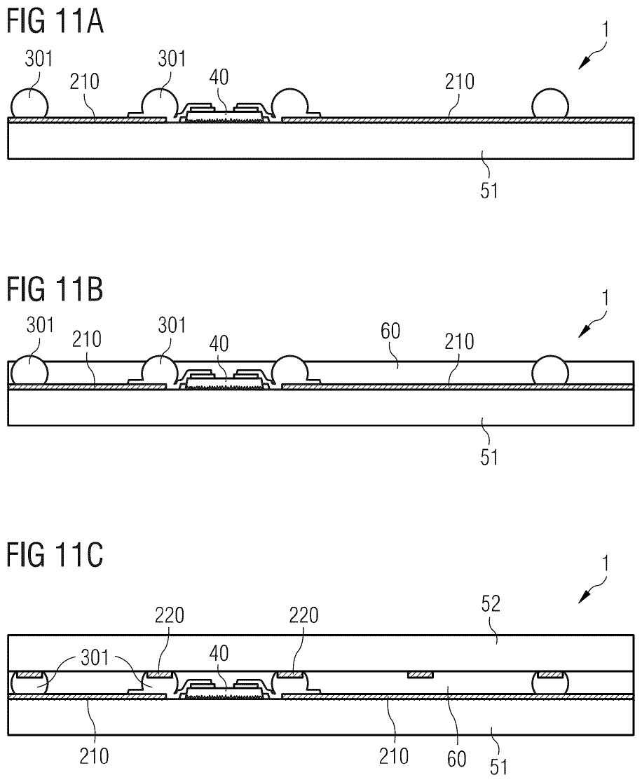

FIGS. 11A to 11C show schematic sectional views of a display unit 1 described herein according to an eighth exemplary embodiment at various stages of a method for its production.

FIG. 11A shows a first step of the method in which a radiation permeable substrate 51 is provided. A first contact layer 21 with a plurality of row lines 210 is arranged on the substrate 51. At least one row line 210 has an interruption in the form of a separation 80. An optoelectronic semiconductor component 40 is arranged on the substrate 51. The optoelectronic semiconductor component 40 is arranged on the substrate 51 such that a main emission direction passes through the substrate 51.

Furthermore, the display unit 1 comprises a plurality of connection elements 301 arranged on the first contact layer 21. The connection elements 301 are formed with a metal paste, in particular a silver paste. Alternatively, the connection elements 301 are formed with a radiation permeable conductive material, in particular PEDOT:PSS. For example, the connection elements 301 are applied to the first contact layer 21 by means of screen printing, stencil printing, micro dispensing, laser induced forward transfer (LIFT) or aerosol jetting.

FIG. 11B shows a further step of the method in which a joining layer 60 is applied to the substrate 51. The joining layer 60 does not protrude beyond the connection elements 301 in the vertical direction. In other words, the connection elements 301 remain free of the material of the joining layer 60 on their side facing away from the substrate 51. The joining layer 60 is applied to the substrate 51 by means of printing or dispensing, for example.

FIG. 11C shows a further step of the method, in which a cover layer 52 is arranged on the joining layer 60. The cover layer 52 comprises a second contact layer 22 with a plurality of column lines 22. The cover layer 52 is aligned laterally to the substrate 51 in such a way that in each case a connection element 301 meets a column line 220 assigned to it.

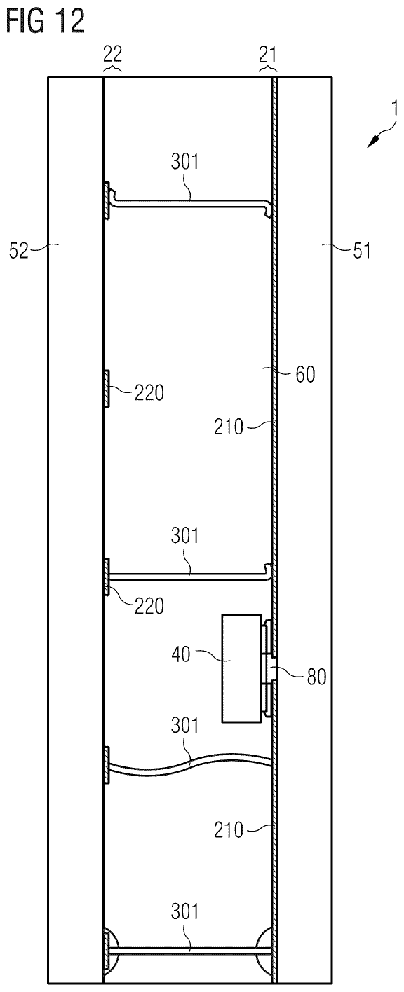

FIG. 12 shows a schematic sectional view of a display unit 1 described herein according to a ninth exemplary embodiment. The ninth exemplary embodiment shown in FIG. 12 essentially corresponds to the sixth exemplary embodiment shown in FIG. 8. In contrast to the sixth exemplary embodiment, the ninth exemplary embodiment comprises various configurations of connection elements 301 in a joining layer 60. The basic idea is based on an integration of thin metal threads in the joining layer 60. For example, the connection elements 301 are formed with copper, silver or gold threads.

The metal threads can be bonded to the first contact layer 21 and the second contact layer 22 using adhesive. Alternatively, the metal thread can have a greater length than the thickness of the joining layer 60 and thus establish contact between the contact layers 21, 22 by compression. The metal thread can optionally be kinked at one or both ends in order to achieve better contact with the contact layers 21, 22.

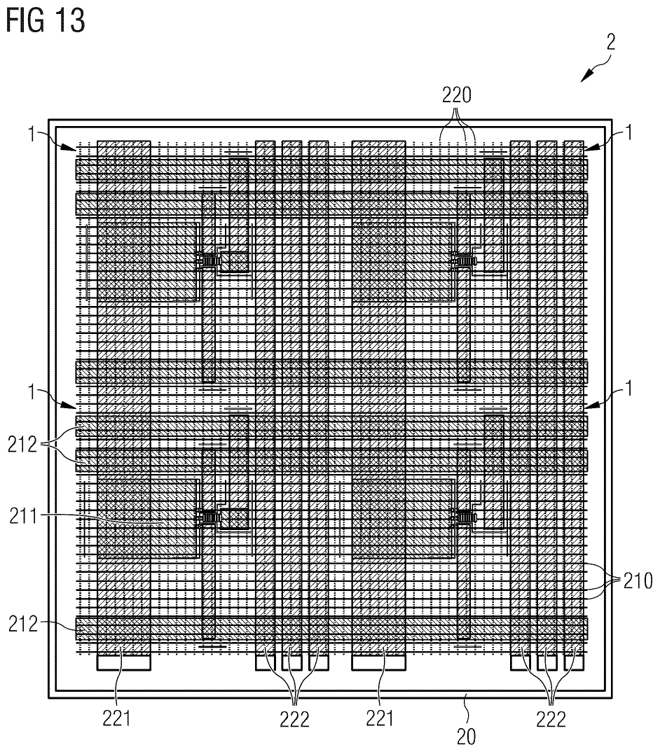

FIG. 13 shows a schematic top view of a display device 2 described herein according to a first exemplary embodiment. The display device 2 comprises a plurality of display units 1 arranged in a frame body 20. The display units 1 are electrically controlled via common first and second row line bundles 211, 212 and second column line bundles 221, 222.

The row spacing 210D of the row lines 210 of all display units 1 of the display device 2 is the same. The column spacing 220D of the column lines 220 of all display units 1 of the display device 2 is the same. The width of the row lines 210 and the column lines 220 is the same in all display units 1. The row spacing 210D deviates by less than 10% from the column spacing 220D. The row spacing 210D is equal to the column spacing 220D.

The frame body 20 completely surrounds the display units 1. In plan view, the frame body 20 has a rectangular shape. The frame body 20 comprises an upper side and a lower side opposite the upper side. Furthermore, the frame body comprises a left and a right side. The row lines 210 are aligned parallel to the lower side and the upper side of the frame body 20. The column lines 220 are aligned parallel to the left and right sides of the frame body 20. This advantageously results in a particularly high radiation permeability of the display device 2 for a viewer.

The invention is not limited by the description based on the exemplary embodiments. Rather, the invention includes any new feature as well as any combination of features, which includes in particular any combination of features in the patent claims, even if this feature or combination itself is not explicitly stated in the patent claims or exemplary embodiments.

The invention claimed is:

1.-20. (canceled)

21. A display unit comprising:
a first contact layer;
a second contact layer;
a plurality of connection region; and
a plurality of optoelectronic semiconductor components,
wherein the first contact layer has a plurality of row lines at a row spacing from one another,
wherein the second contact layer has a plurality of column lines at a column spacing from one another,
wherein the first contact layer and the second contact layer are arranged stacked,
wherein each of the connection regions electrically conductively connects at least one row line to at least one column line, and
wherein the row spacing deviates by less than 50% from the column spacing.

22. The display unit according to claim 21, wherein each of the connection regions comprises a plurality of connection elements.

23. The display unit according to claim 22, wherein each of the connection elements is arranged at crossing points of a row line and a column line.

24. The display unit according to claim 22, wherein the connection elements comprise a metal.

25. The display unit according to claim 21, wherein the connection regions comprise a radiation permeable and electrically conductive material.

26. The display unit according to claim 21, wherein the first contact layer and the second contact layer are arranged on a radiation permeable substrate.

27. The display unit according to claim 26, wherein the first contact layer is arranged on a side of the substrate opposite to the second contact layer.

28. The display unit according to claim 26, wherein the first contact layer and the second contact layer are arranged on a common side of the substrate.

29. The display unit according to claim 21, wherein the first contact layer is arranged on a substrate and the second contact layer is arranged on a cover layer.

30. The display unit according to claim 29, further comprising a radiation permeable joining layer arranged between the substrate and the cover layer.

31. The display unit according to claim 21, wherein the row lines and the column lines intersect at an intersection angle of at least 45°.

32. The display unit according to claim 21, wherein the row lines and the column lines have a constant width.

33. A method for producing a display unit, the method comprising:
providing a first contact layer on a substrate;
providing a second contact layer;
structuring the first contact layer into a plurality of row lines at a row spacing from each other;
structuring the second contact layer into a plurality of column lines at a column spacing from each other;
forming a plurality of connection regions, each of which electrically conductively connecting at least one row line to at least one column line; and
arranging a plurality of optoelectronic semiconductor components on the display unit.

34. The method according to claim 33, wherein the second contact layer is arranged on a side of the substrate opposite to the first contact layer.

35. The method according to claim 33, wherein the connection regions are placed in a recess in the substrate.

36. The method according to claim 33, wherein the first contact layer is arranged on a side of the second contact layer facing away from the substrate.

37. The method according to claim 33, wherein the second contact layer is arranged and structured on a radiation permeable cover layer.

38. The method according to claim 37, wherein the substrate and the cover layer are joined together via a joining layer.

39. A display device comprising:
a plurality of display units according to claim 21.

40. The display unit according to claim 21, wherein at least some of the row lines and/or some of the column lines are formed electrically separated from each other.
